(19) United States
(12) Patent Application Publication
(10) Pub. No.: US 2016/0041228 A1
(43) Pub. Date: Feb. 11, 2016

(54) ELECTRIC MACHINE FAULT DETECTION

(71) Applicant: THE UNIVERSITY OF NOTTINGHAM, Nottingham (GB)

(72) Inventor: Chris Gerada, Nottingham (GB)

(21) Appl. No.: 14/782,540

(22) PCT Filed: Apr. 7, 2014
(86) PCT No.: PCT/GB2014/051075

§ 371 Date: Oct. 5, 2015

(30) Foreign Application Priority Data
Apr. 5, 2013 (GB) 1306194.0

(51) Int. Cl. G01R 31/34; H02K 11/00; H02K 3/30; H02K 3/02; H02K 3/28; H02K 1/27

(52) U.S. Cl. CPC G01R 31/346; H02K 3/28; H02K 1/27; H02K 3/30; H02K 3/02; H02K 11/00

(57) ABSTRACT

A electric machine (150) comprising a rotor or stator winding (210a, 210b, 210c), wherein the winding (210a, 210b, 210c) comprises a cable that includes an inner conductor (a, b, c) and an outer conductor (a″, b″, c″) and an insulator separating the inner conductor (a, b, c) from the outer conductor (a″, b″, c″).

The invention relates to an electric machine (e.g. a motor or generator) with improved fault detection and to a method of determining a fault in an electric machine.

Electric machines comprise wound coils that are used to either generate electrical power from mechanical power, or which are used to convert electrical power into mechanical power. Such windings may be on a stationary part of the machine (stator), or on a moving part of the machine (rotor). Faults in windings of electric machines are undesirable. For convenience, the present invention will be described mainly with reference to a motor, but it should be understood that the invention applies equally to generators.

Electric machines typically comprise a stator with multiple winding phases. Stator winding faults due to insulation failures are a common fault condition. These often start as inter-turn failures, in which a short circuit develops between turns of a particular winding. Such failures can quickly develop into short circuits to ground, which lead to large currents that can damage the stator and lead to further failure in the drive system. Stator over current may, for instance, damage the windings and may partially demagnetize rotor permanent magnets.

In some motors, the insulation's degradation is principally due to the use of voltage source converters (VSCs) for driving the motors. VSCs generate the voltage waveforms for supplying the motor by pulse width modulation (PWM). The PWM synthesizes low frequency voltages for the motor using high frequency voltage pulses. Although PWM allows high power efficiency and motor supply voltages that are free from low order harmonics, which are responsible for torque and speed oscillations, it generates high frequency harmonics and very steep rate of voltage rise that can increase the stress on turn-to turn or turn-to-ground insulation.

In recent years, these problems have been exacerbated by the introduction of new technologies for power switches, such as SiC (silicon carbide) or GaN (gallium nitride) devices. Such devices enable higher switching frequencies, decreasing the power losses and allowing a reduction of VSCs sizes and costs, but may also result in increased stress on winding insulation.

Failures in winding insulation are particularly problematic in safety critical applications, such as motors in nuclear power applications, or in aircraft (fixed wing or rotorcraft). Taking the latter case as an example, such a failure may lead to a fire which has the potential to create a dangerous situation for the entire aircraft.

The current resulting from an external short circuit (e.g. to ground) may be limited by the machine inductance. The risks associated with such a fault can be reduced by designing the machine to have higher inductance, thereby limiting these currents. A disadvantage of this approach is that it tends to result in a larger machine, lower power factor and a larger converter kVA.

Mitigation of internal short circuit faults is more problematic as it is typically very difficult to detect such faults. If such faults are detected there are only very limited ways in which they can be mitigated. The situation is especially serious when dealing with permanent magnet machines as the magnet excitation cannot be turned off.

A method of detecting internal short circuit faults in electric machines before they occur (or become problematic) is desired.

Permanent magnet synchronous machines (PMSMs) are a type of electric motor/generator that tend to have relatively high speed operation, precise torque control, high power to weight ratio, and high efficiency. For all these reasons PMSMs are currently widely applied and are the object of ongoing research activities. In particular, a number of applications for PMSMs are envisaged in relation to the More Electric Aircraft (MEA) concept. The MEA concept envisages replacing hydraulic, pneumatic and mechanical systems with electrically-powered systems in order to achieve advantages in terms of reduced weight, lower cost, increased safety, and enhanced reliability. PMSMs are particularly suitable for such applications due to their compact structure and high power and torque density.

However, the safety critical nature of such applications mean that some form of electric motor on-line fault monitoring and diagnosis would be desirable.

A number of fault detection techniques for electric motors have been developed during recent years in order to try to obtain early detection of stator faults and to prevent subsequent damage. Such techniques include: noise and vibration monitoring, acoustic noise measurements, stator current monitoring, torque and speed harmonic analysis and high frequency injection method. Nevertheless the early stages of winding deterioration remain difficult to detect, and an effective method for detecting such faults is desirable.

It is an object of the invention to address at least some of the foregoing problems.

According to the invention, there is provided an electric machine comprising a rotor or stator winding, wherein the winding comprises a cable that includes an inner conductor and an outer conductor, and an insulator separating the inner conductor from the outer conductor.

Providing a winding comprising a cable with an inner conductor surrounded by an outer conductor allows a failure of the insulation between the inner and outer conductors to be detected before a short circuit between turns of a winding occurs, by detecting a short circuit between the inner and outer conductor of the winding. The detection of such a short circuit therefore allows incipient turn-to-turn faults to be detected and addressed before they take place.

This approach is applicable to rotor windings as well as stator windings, and is not restricted to a particular class of electric machines, such as permanent magnet synchronous machines. Monitoring the outer conductor of a winding according to an embodiment can be used to determine a fault condition of a winding before it develops into a turn to turn fault.

The cable may be a coaxial cable, in which the inner conductor and outer conductor are coaxial, and the outer conductor is separated from the inner conductor by insulation around the inner conductor.

The cable may a Litz cable, in which the inner conductor comprises a plurality of insulated wires. The cable may comprise a further insulator between the insulated wires and the outer conductor. The outer conductor may comprise a conducting sleeve around the inner conductor. The outer conductor may be provided with an insulating layer (e.g. an insulating sleeve) around the exterior thereof.

The outer conductor may completely or mostly surround the insulator around the inner conductor. The outer conductor may comprise at least one conductor element wound helically around the insulator, which may surround the inner conductor. Each conductor element of the outer conductor may be a flat ribbon shaped wire, or may be a wire with a substantially circular cross section. The outer conductor may be a thin foil rolled around the insulator, the insulator in turn being disposed around the inner conductor. There may be gaps in the outer conductor and/or the insulator.

The motor may be a permanent magnet synchronous machine, and the winding may comprise a plurality of stator phase windings.

There may be three phase windings, each phase winding comprising a cable with an inner conductor and a outer conductor, and an insulator separating the inner conductor from the outer conductor.

Each winding may comprise a first end and a second end and the inner conductors of each winding may be connected together at the second end of each winding in a wye configuration.

The outer conductors of each winding may be connected together in a wye configuration at:
the second end of the winding;
the first end of the winding
or a point between the first and second end of the winding.

The electric machine may further comprise a fault detection circuit connected to the outer conductor, the fault detection circuit being configured to monitor an electrical property of the outer conductor to determine a fault condition.

The fault detection circuit may comprise a processor.

The electrical property of the outer conductor mat comprise a current or a voltage.

The fault detection circuit may be arranged to monitor a current in the outer conductor through a star point of the wye configuration.

The fault detection circuit may be arranged to monitor the current provided to the inner conductor of each winding.

The fault detection circuit may be configured to determine a fault condition based, at least in part, on at least one of:
a harmonic content of the monitored current in the inner or outer conductor; and
an amplitude of the third order harmonic content of the monitored currents in the inner or outer conductor.

The fault detection circuit may be configured to perform a Clarke transformation on monitored voltages of the outer conductor and monitored currents of the inner conductor, and to determine a power in the Clarke reference frame therefrom.

The power may comprise a real power, and the fault detection circuit may be configured to perform a harmonic analysis on the real power, and to determine a fault condition based, at least in part, on the results of the harmonic analysis.

The fault detection circuit may be configured to perform a Park transform on the instantaneous real power prior to performing the harmonic analysis.

The results of the harmonic analysis may comprise an amplitude of a fourth order harmonic, and the fault condition may be determined based, at least in part, on the amplitude of the fourth order harmonic.

The insulator may comprise polyimide, the outer conductor may comprise aluminium, and the cable may comprise a further insulating layer of polyimide surrounding the outer conductor.

The insulator may comprise polyimide and the outer conductor may comprise metallised polyimide.

The insulator may comprise polyimide and the outer conductor may comprise a conductive varnish layer.

There may not be an insulator layer surrounding the outer conductor.

According to a second aspect an aircraft is provided, comprising the electric machine of the first aspect.

According to a third aspect, there is provided a method of monitoring for faults in an electric machine according to the first aspect, the method comprising:
operating the electric machine by rotating a rotor of the machine, and
monitoring at least one electrical property of the inner conductor and/or the outer conductor as the electric machine is operated to determine whether a fault condition exists.

The at least one electrical property may comprise at least one of:
a current flowing through the inner conductor;
a harmonic content of the current flowing through the inner conductor
a third harmonic content of the current provided to the inner conductor; and
a voltage or current of the outer conductor.

The at least one electrical property may comprise the current flowing in the inner conductor of each winding and a voltage of the outer conductor of each phase winding. The method may comprise performing a Clarke transformation on the current flowing in the inner conductor and on the voltages of the outer conductor, and determining a power in the Clarke reference frame based on the voltages and currents.

The power may comprise a real power, and the method may comprise performing a harmonic analysis on the real power.

A Park transform may be performed on the real power prior to performing the harmonic analysis.

Performing the harmonic analysis may comprise determining an amplitude of a fourth order harmonic of the real power in a dq0 reference frame.

In another aspect, a rotor or stator for an electric machine is provided, comprising a winding, the winding comprising a cable that includes an inner conductor and a outer conductor, and an insulator separating the inner conductor from the outer conductor.

Example embodiments of the invention will now be described, with reference to the accompanying drawings, in which:

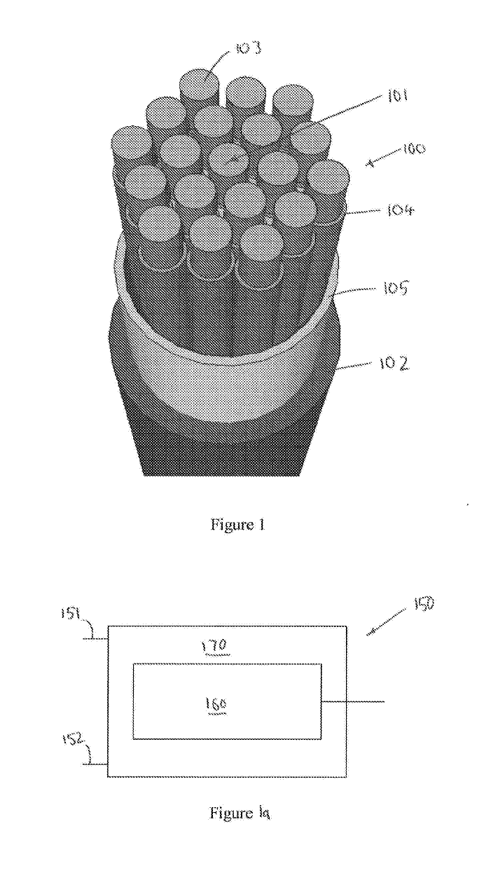

FIG. 1 is a perspective view of a cable of an embodiment;

FIG. 1a is a schematic of a motor according to an embodiment;

FIG. 2 is a circuit diagram of an electric machine according to an embodiment of the invention;

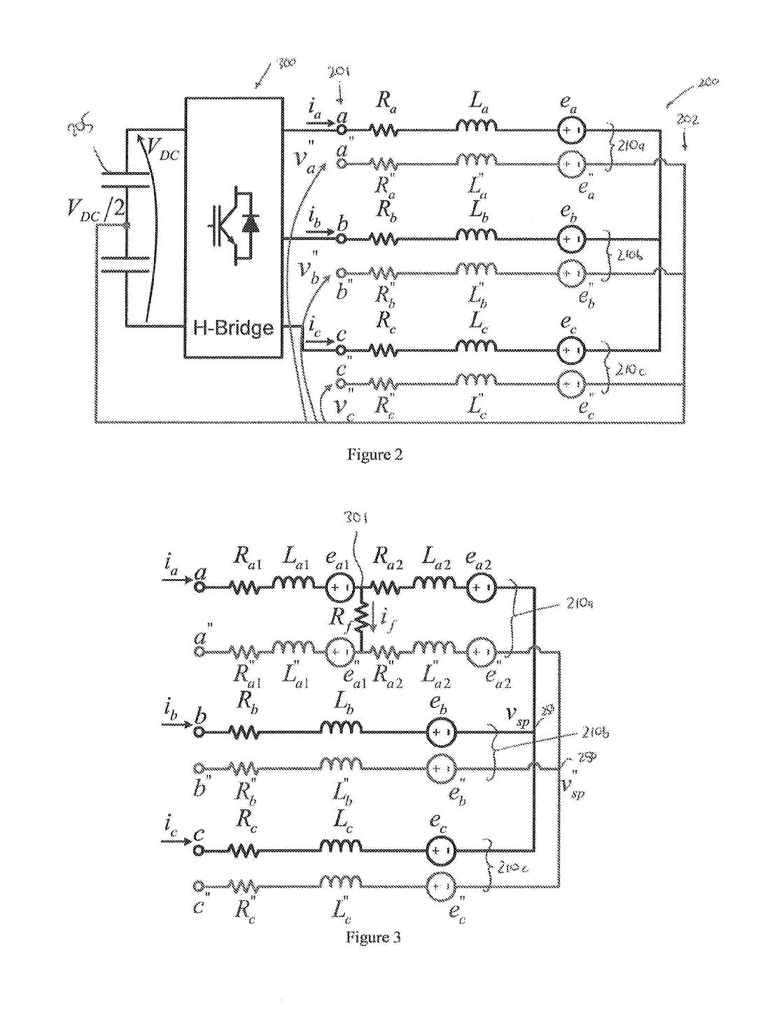

FIG. 3 is a circuit diagram of an electric motor according to an embodiment with a fault condition;

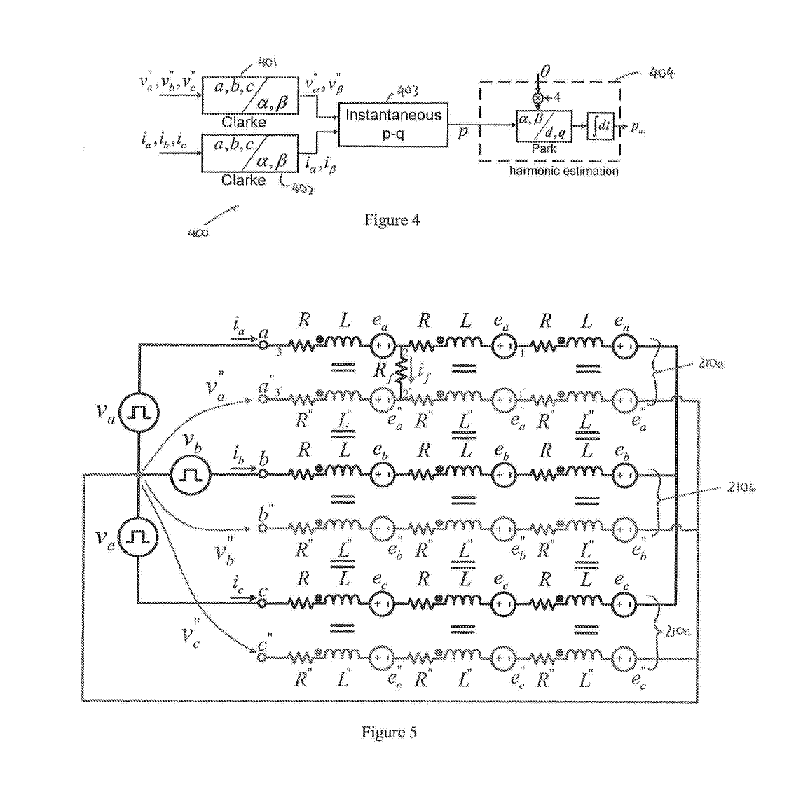

FIG. 4 is a flow diagram of a fault calculation approach according to an embodiment of the invention;

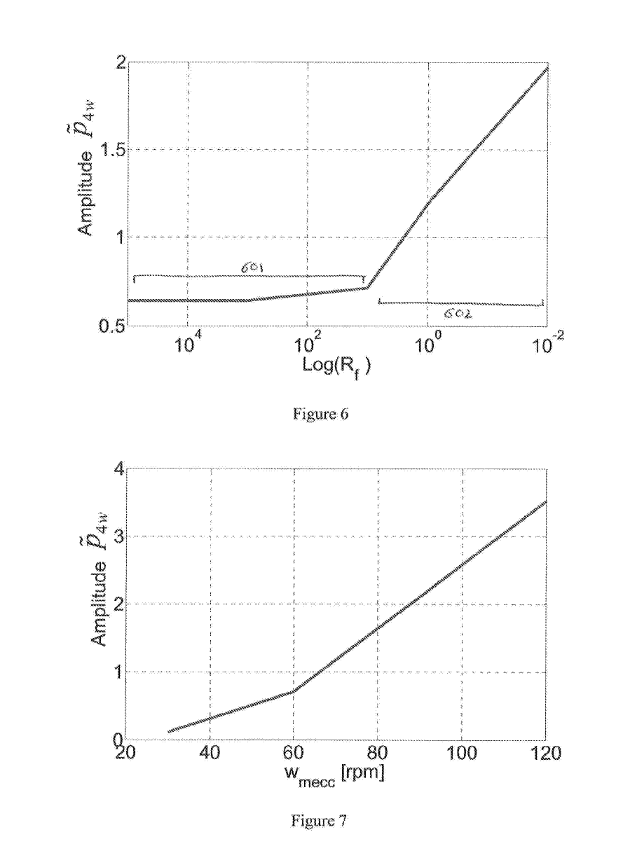

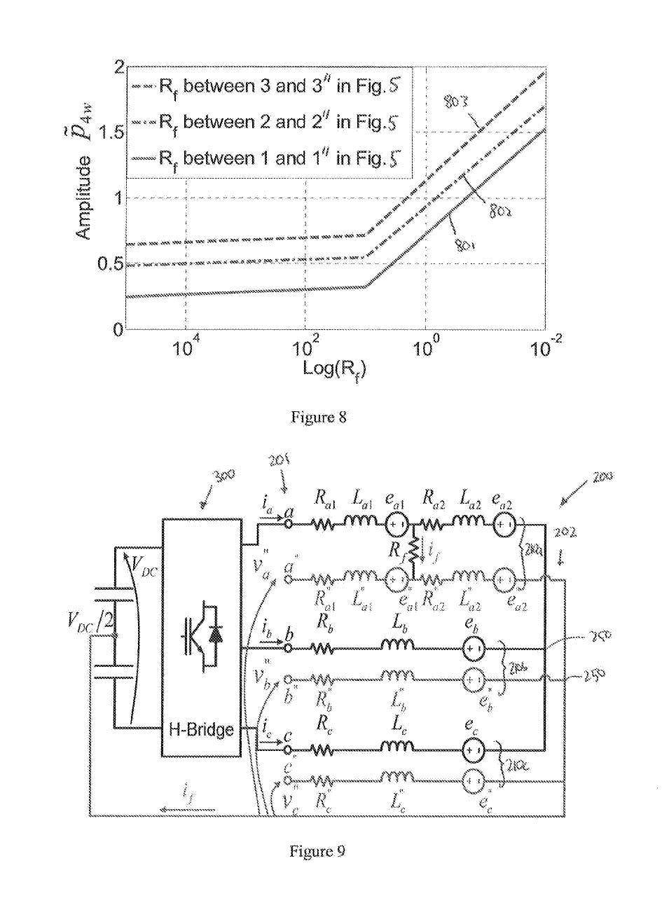

FIG. 5 is a circuit diagram of an electric motor according to an embodiment of the invention showing the monitored currents and measured voltages;

FIG. 6 is a graph of the fourth harmonic of the real power amplitude as a function of the resistance of a short circuit between positions 3 and 3″ of the first phase winding as shown in FIG. 4, determined according to an embodiment showing the detection of a fault at relatively low motor speed;

FIG. 7 is a graph of the fourth harmonic of the real power amplitude as a function of the rotational speed of the motor, determined according to an embodiment;

FIG. 8 is a graph of the fourth harmonic of the real power amplitude as a function of the resistance of a short circuit between positions 1 and 1″, 2 and 2″ and 3 and 3″ respectively; and

FIG. 9 is a circuit diagram illustrating monitoring of the current in the outer conductor flowing through a star point;

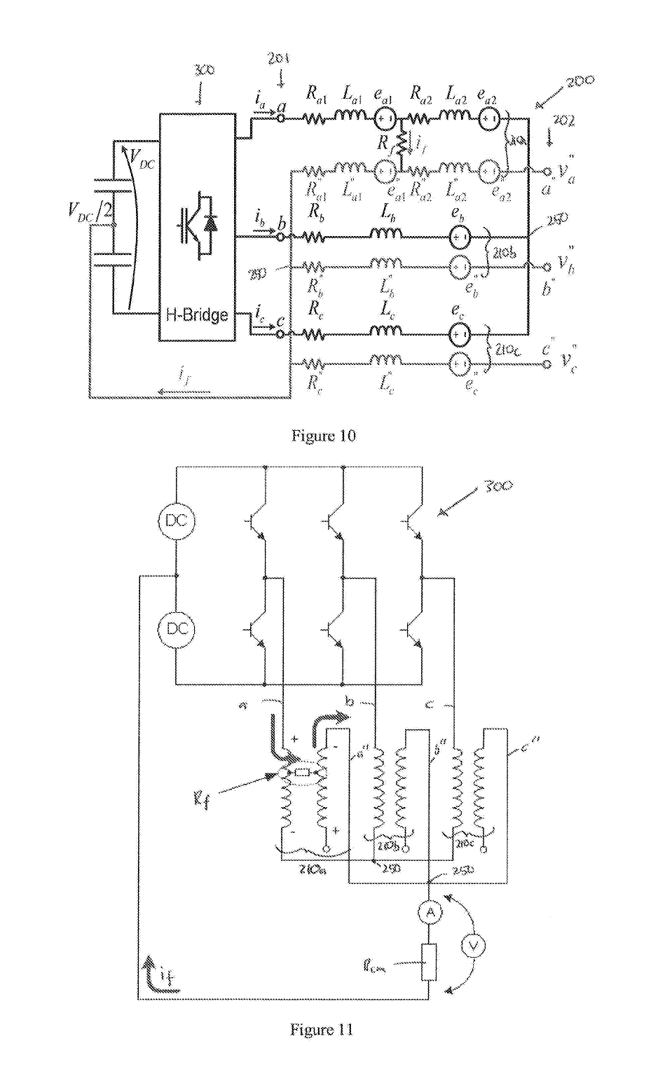

FIG. 10 is a circuit diagram of an arrangement in which the star point of the inner and outer conductor are respectively at opposite ends of each phase winding;

FIG. 11 is a circuit diagram illustrating a fault current for an embodiment similar to that shown in FIG. 10;

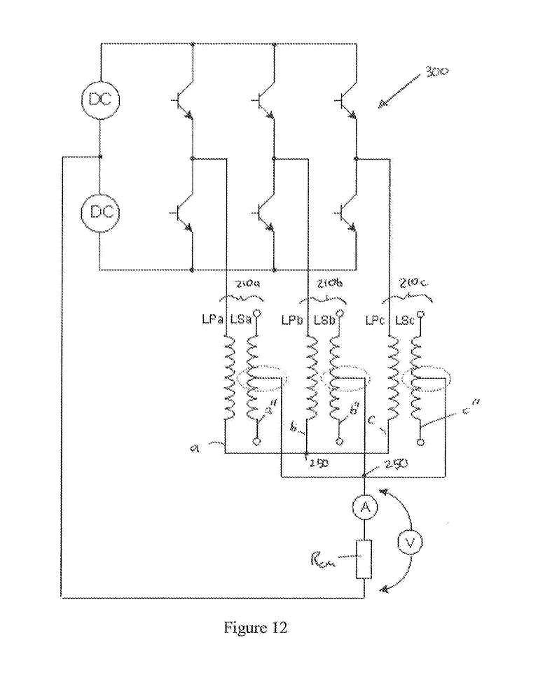

FIG. 12 is a circuit diagram of an arrangement in which the star point of the outer conductor is halfway between the start and end of the phase winding;

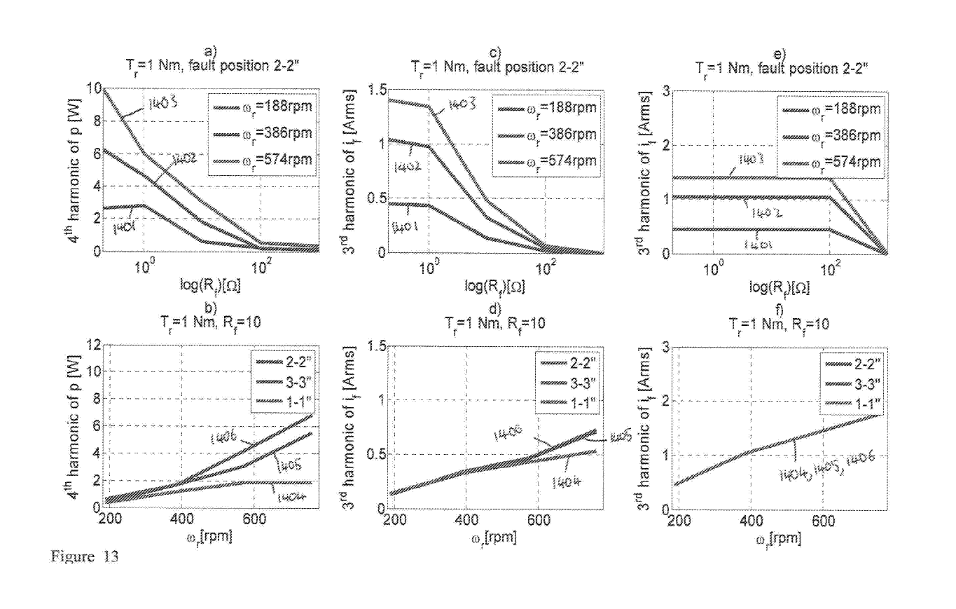

FIGS. 13a to 13f shows graphs of results obtained using fault detection methods according to embodiments;

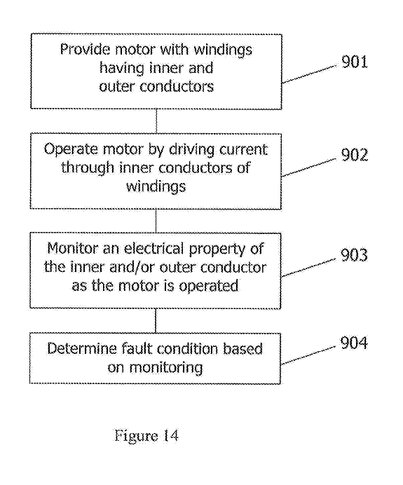

FIG. 14 is a flow diagram of a method according to an embodiment of the invention.

A cable suitable for use in an embodiment of the invention is shown in FIG. 1. The cable 100 comprises an inner conductor 101, an outer conductor 102 and an insulator separating the inner conductor 101 from the outer conductor 102. The inner conductor 101 comprises a bundle of conducting wires 103. The separating insulator comprises a wire insulating sleeve 104 around each wire 103 and a bundle insulating layer 105 around the wires 103. In other embodiments the separating insulator may comprise only the wire insulating sleeve 104 of each wire, or only the bundle insulating layer 105. One of the wire insulating sleeves 104 or the bundle insulating layer can be omitted.

The bundle insulating layer 105 is in turn surrounded by the outer conductor 102, which surrounds the bundle insulating layer 105. A further insulating layer (not shown) may be provided over the outer conductor 102. The cable 100 may be a Litz cable.

The use of a cable with an inner conductor 101 and an outer conductor 102 provides two independent circuits for each of the phases of a motor. One conductor of the wire or cable (e.g. the outer conductor 102) may be effectively open circuit, for instance being connected to a high input impedance voltage measurement circuit. The other conduction layer (e.g. the inner conductor 101) may be connected to a motor power source.

For instance, the inner conductor 101 may be provided with motor power, and the outer conductor 102 may be used to monitor the health of the motor winding. Before a turn-turn short circuit occurs, there will first be a turn-conducting layer/sheath contact. In the case of the cable 100 shown in FIG. 1, if the separating insulators 104, 105 fail, contact would be made between the inner conductor 101 and the outer conductor 102. However, the failure would not have yet reached the inner conductor 101 of the next wire, so turn-turn failure would not yet have occurred. In a similar way a turn-ground or a phase-to-phase failure is also pre-empted by short circuits between the inner conductor 101 and outer conductor 102.

FIG. 1a shows a schematic of a motor 150 according to an embodiment. The motor comprises a rotor 160 and a stator 170. The stator 170 is wound with at least one phase. Each phase of the stator 170 comprises a cable 100 with an inner conductor 101 and outer conductor 102 surrounding the inner conductor 101 and separated therefrom by an insulator. A first set of connections 151 are provided for making electrical contact with the inner conductors of each phase, and a second set of connectors 152 is provided for making electrical contact with the outer conductor of each phase. The rotor 160 comprises a permanent magnet.

Referring to FIG. 2, a circuit diagram of a three phase PMSM stator 200 according to an embodiment is shown, connected to a motor driver (or power converter) 300. The motor driver 300 comprises an H-bridge driver, which is supplied with a DC voltage, V_{DC} by a DC power supply, which may be a pair of cells 205 in series. A reference voltage V_{DC}/2 is therefore defined between the pair of cells 205.

The PMSM stator comprises three phase windings 210a, 210b, 210c. Each phase winding 210a, 210b, 210c comprises a cable with an inner conductor and an outer conductor.

For each stator phase the inner and outer conductors of the cable form two conductors, electrically insulated, wound around the same former and having the same number of turns. Each phase winding may therefore have three symmetrical windings (a, b, c in FIG. 2), due to the inner conductor of the cable, that are connected as usual to the power converter supplying the motor, and three additional windings, denoted with a″, b″, c″ in FIG. 2 due to the outer conductor of the cable, that can be left in open circuit (or connected to a high impedance).

The conductors of each phase winding are represented by a series combination of a resistive element R, an inductive element L, and a voltage source e which represents back electromotive force generated in the conductor. Circuit elements representing the first, second and third phase windings are respectively denoted by the subscript a, b or c, and circuit elements representing the outer conductors are denoted by a double dash: ″.

Magnetic coupling exists between the inner and outer conductors of each phase 210a, 210b, 210c and magnetic coupling also exists between the inner and outer conductors of different phases. The outer conductors of each phase winding are not used to supply power to the motor, but their voltages may be employed to obtain information about the state of the machine, for instance to determine a fault condition. As the load current does not flow through the outer conductor, the outer conductor may have a smaller cross sectional area than the inner conductor, at least partly reducing the problems of size and weight resulting from the use of a cable with an inner and outer conductor.

The inner conductors a, b, c of each phase winding 210a, 210, 210c are connected at a first end 201 to the motor driver 300, and at a second end 202 to each other in a wye configuration. The outer conductors a″, b″, c″ are connected at a second end 202 to V_{DC}/2 and are represented as open circuit at the first end 201 (which may effectively be the case where they are connected to a further circuit with a high input impedance, such as a voltage monitoring circuit).

The voltage at the first end 201 of each of the outer conductors a″, b″, c″ (relative to V_{DC}/2) is denoted by vₐ″, v_{b}″ and v_{c}″ for the first, second and third phase winding respectively. The current through the inner conductor of each of the first, second and third phase winding 210a, 210b, 210c is respectively denoted by iₐ, i_{b} and i_{c}.

The equations that describe a healthy PMSM (with no fault condition) in the stator reference frame are as follows:

$$[ {V}_{sh} ] = [ {R}_{s} ] \cdot [ {i}_{sh} ] + [ {L}_{s} ] \cdot \frac{d}{d t} [ {i}_{sh} ] + [ {e}_{sh} ] \qquad ( equation 1 )$$

where the voltages and currents can be expressed as

[vₛₕ]=[Vₐ,V_{b},V_{c},vₐ″,v_{b}″,v_{c}″]^{t}=[[Vₛ],[vₛ″]]^{t},

[iₛₕ]=[iₐ,i_{b},i_{c},iₐ″,i_{b}″,i_{c}″]^{t}=[[iₛ],[iₛ″]]^{t},

[eₛₕ]=[eₐ,eₕ,e_{c},eₐ″,e_{b}″,e_{c}″]^{t}=[[eₛ],[eₛ″]]^{t}.

It is assumed that the PMSM is symmetric and there is no magnetic saturation. Therefore the matrix of resistances and inductances can be expressed as:

$$[ {R}_{s} ] = [ \begin{matrix}{R}_{a} & 0 & 0 & 0 & 0 & 0 \\ 0 & {R}_{b} & 0 & 0 & 0 & 0 \\ 0 & 0 & {R}_{c} & 0 & 0 & 0 \\ 0 & 0 & 0 & {R}_{a}^{″} & 0 & 0 \\ 0 & 0 & 0 & 0 & {R}_{b}^{″} & 0 \\ 0 & 0 & 0 & 0 & 0 & {R}_{c}^{″}\end{matrix} ] \\ [ {L}_{s} ] = [ \begin{matrix}{L}_{a} & {M}_{ab} & {M}_{a c} & {M}_{{aa}^{″}} & {M}_{{ab}^{″}} & {M}_{a {c}^{″}} \\ {M}_{ba} & {L}_{b} & {M}_{bc} & {M}_{{ba}^{″}} & {M}_{{ba}^{″}} & {M}_{{bc}^{″}} \\ {M}_{ca} & {M}_{cb} & {L}_{c} & {M}_{{ca}^{″}} & {M}_{{cb}^{″}} & {M}_{{cc}^{″}} \\ {M}_{{aa}^{″}} & {M}_{{ba}^{″}} & {M}_{{ca}^{″}} & {L}_{a}^{″} & {M}_{{a}^{″} {b}^{″}} & {M}_{{a}^{″} {c}^{″}} \\ {M}_{{ab}^{″}} & {M}_{{bb}^{″}} & {M}_{{cb}^{″}} & {M}_{{a}^{″} {b}^{″}} & {L}_{b}^{″} & {M}_{{b}^{″} {c}^{″}} \\ {M}_{a {c}^{″}} & {M}_{{bc}^{″}} & {M}_{{cc}^{″}} & {M}_{{a}^{″} {c}^{″}} & {M}_{{b}^{″} {c}^{″}} & {L}_{c}^{″}\end{matrix} ]$$

$$with {R}_{a} = {R}_{b} = {R}_{c} = R and {L}_{a} = {L}_{b} = {L}_{c} = L .$$

It can be expected that the inner and outer conductor of each phase 210a, 210b, 210c should present the same value of self-inductance and the same flux linkage (i.e. the same back electromotive force) because they are wound around the same coil former and have the same number of turns. Furthermore the magnetic coupling factor between the inner and outer conductor of a given phase winding is approximately unity.

Hence it is possible to approximate:

Lₐ=Lₐ″=M_{aa″}=L,

M_{ab″}=M_{ac″}=M_{ba″}=M_{bc″}=M_{cb″}=M_{ca″}=M

and

[eₛ]=[eₛ″].

The matrices of resistances and inductances are therefore:

$$[ {R}_{s} ] = [ \begin{matrix}[ R ] & [ 0 ] \\ [ 0 ] & [ {R}^{″} ]\end{matrix} ] , [ {L}_{s} ] = [ \begin{matrix}[ L ] & [ L ] \\ [ L ] & [ L ]\end{matrix} ]$$

where the sub-matrices are:

$$[ R ] = [ \begin{matrix}R & 0 & 0 \\ 0 & R & 0 \\ 0 & 0 & R\end{matrix} ] , [ {R}^{″} ] = [ \begin{matrix}{R}^{″} & 0 & 0 \\ 0 & {R}^{″} & 0 \\ 0 & 0 & {R}^{″}\end{matrix} ] , [ L ] = [ \begin{matrix}L & M & M \\ M & L & M \\ M & M & L\end{matrix} ]$$

Since the outer conductors are in open circuit it is possible to neglect from the equation the current [iₛ″], because substantially no current will flow through the outer conductor, hence:

$$\{ \begin{matrix}[ {V}_{s} ] = [ {R}_{s} ] \cdot [ {i}_{s} ] + [ {L}_{s} ] \cdot \frac{d}{d t} [ {i}_{s} ] + [ {e}_{s} ] \\ [ {v}_{s}^{″} ] = [ {L}_{s} ] \cdot \frac{d}{d t} [ {i}_{s} ] + [ {e}_{s} ]\end{matrix} \qquad ( equation 2 )$$

The first row in equation 2 is that used to describe a healthy PMSM in the stator reference frame. The second row of equation 2 shows that the voltages of the outer conductors are equal to those of the inner conductors, less the voltage dropped by the drive current in the inner conductor resistance. This allows a significant problem with prior art fault detection techniques to be overcome.

It is known to monitor the harmonic component of stator voltages and currents in order to get information on the state of the motor. However, the stator voltages may are typically affected by the motor drive, which often comprises a pulse width modulation converter which makes it difficult to acquire and analyze harmonic components of stator current and voltage.

Embodiments of the present invention overcome these problems by providing voltages [vₛ″] measured on the outer conductor of each stator phase winding, which are totally decoupled from any pulse width modulation effects, and which can be easily employed instead of [vₛ] for detection of electric faults in the windings.

An example of a motor with a fault condition will be considered, with reference to FIG. 3. Faults in the stator windings are typically due to a deterioration of the winding insulation. Such deterioration can eventually cause a ‘turn to turn’ or a ‘turn to ground’ fault. Where a winding comprising an inner conductor and an outer conductor around the inner conductor and separated from the inner conductor by an insulator, it is most probable that the insulation failure will initially occur between the inner and outer conductor layers of the cable. Early detection of such deterioration in the insulation layer of the cable can eliminate subsequent damage, thereby reducing repair costs and motor outage time.

FIG. 3 shows a circuit representing a stator with an incipient fault in the first phase 210a. The inner conductor a of phase 210a and the outer conductor a″ of phase 210a are represented as two sub-windings in series a₁, a₂ for a, and a₁″, a₂″ for a″ respectively. The insulation layer between the inner conductor a, and the outer conductor a″ of the cable is degraded at the point 301 between the two sub-windings. A resistance R_{f} is use to model the damage in the isolation layer. Its value depends on the fault severity: when R_{f} decreases toward zero, the fault represents a full short circuit between the inner and outer conductors a, a″.

In FIG. 3, Rₐ₁, Lₐ₁ and eₐ₁ are the resistance, self-inductance and the back EMF of sub-winding a₁. Rₐ₂, Lₐ₂ and eₐ₂ are the corresponding parameters of sub-winding a₂. The same notation and equivalent circuit is applied to the sub-windings of a″.

Considering a number N of turns for the windings and a damage in the insulation layer coinciding with turn n, it is possible to write

Lₐ₁=Lₐ₁″=(1−μ)²L

and

Lₐ₂=Lₐ₂″=μ²L,

where

μ=n/N.

Also, introducing Mₐ₁ₐ₂ as the mutual inductance between sub-windings a₁ and a₂ it follows that:

Mₐ₁ₐ₂=M_{a1″a2″}=μ(1−μ)L

M_{a1a1″}=Lₐ₁,M_{a2a2″}=Lₐ₂

M_{a1b}=M_{a1″b}=M_{a1c}=M_{a1″c}=(1−μ)M

M_{a2b}=M_{a2″b}=M_{a2c}=M_{a2″c}=μM

Rₐ₁=(1−μ)R,Rₐ₂=μR,Rₐ₁″=(1−μ)R″,Rₐ₂″=μR^{″}

eₐ₁=eₐ₁″=(1−μ)eₐ,eₐ₂=eₐ₂″₂=μeₐ (equation 3)

Setting up the mesh equations for the circuit in FIG. 3:

$$( equation 4 ) \\ [ \begin{matrix}{v}_{a 1} \\ {v}_{a 2} \\ {V}_{b} \\ {V}_{c} \\ {v}_{a 1}^{″} \\ {v}_{b}^{″} \\ {v}_{c}^{″}\end{matrix} ] = {[ 1 ]}_{8 \times 8} \cdot [ \begin{matrix}{R}_{a 1} \\ {R}_{a 1} \\ R \\ R \\ {R}_{a 1}^{″} \\ {R}_{a 1}^{″} \\ {R}_{b}^{″} \\ {R}_{c}^{″}\end{matrix} ] \cdot [ \begin{matrix}{i}_{a} \\ {i}_{a} - {i}_{f} \\ {i}_{b} \\ {i}_{c} \\ 0 \\ {i}_{f} \\ 0 \\ 0\end{matrix} ] + [ \begin{matrix}{L}_{a 1} & {M}_{a 1 a 2} & {M}_{a 1 b} & {M}_{a 1 c} & {M}_{a 1 a {1}^{″}} & {M}_{a 1 a {2}^{″}} & {M}_{a 1 {b}^{″}} & {M}_{a 1 {c}^{″}} \\ {M}_{a 1 a 2} & {L}_{a 2} & {M}_{a 2 b} & {M}_{a 2 c} & {M}_{a 2 a {1}^{″}} & {M}_{a 2 a {2}^{″}} & {M}_{a 2 {b}^{″}} & {M}_{a 2 {c}^{″}} \\ {M}_{a 1 b} & {M}_{a 2 b} & L & M & {M}_{ba {1}^{″}} & {M}_{ba {2}^{″}} & L & M \\ {M}_{a 1 c} & {M}_{a 2 c} & M & L & {M}_{ca {1}^{″}} & {M}_{ca {2}^{″}} & M & L \\ {M}_{a 1 a {1}^{″}} & {M}_{a 2 a {1}^{″}} & {M}_{ba {1}^{″}} & {M}_{ca {1}^{″}} & {L}_{a 1} & {M}_{a 1 a 2} & {M}_{a 1 {b}^{″}} & {M}_{a 1 {c}^{″}} \\ {M}_{a 1 a {2}^{″}} & {M}_{a 2 a {2}^{″}} & {M}_{ba {2}^{″}} & {M}_{ca {2}^{″}} & {M}_{a 1 a 2} & {L}_{a 2} & {M}_{a 2 {b}^{″}} & {M}_{a 2 {c}^{″}} \\ {M}_{a 1 {b}^{″}} & {M}_{a 2 {b}^{″}} & L & M & {M}_{a {1}^{″} {b}^{″}} & {M}_{a {2}^{″} {b}^{″}} & L & M \\ {M}_{a 1 {c}^{″}} & {M}_{a 2 {c}^{″}} & M & L & {M}_{a {1}^{″} {c}^{″}} & {M}_{a {2}^{″} {c}^{″}} & M & L\end{matrix} ] \cdot \frac{d}{d t} [ \begin{matrix}{i}_{a} \\ {i}_{a} - {i}_{f} \\ {i}_{b} \\ {i}_{c} \\ 0 \\ {i}_{f} \\ 0 \\ 0\end{matrix} ] + [ \begin{matrix}{e}_{a 1} \\ {e}_{a 2} \\ {e}_{b} \\ {e}_{c} \\ {e}_{a 1}^{″} \\ {e}_{a 2}^{″} \\ {e}_{b}^{″} \\ {e}_{c}^{″}\end{matrix} ]$$

From FIG. 3 and the voltage equations, we also can write:

$$\{ \begin{matrix}{v}_{a 1} + {v}_{a 2} = {V}_{a} \\ {v}_{a 1}^{″} + {v}_{a 2}^{″} = {v}_{a}^{″} \\ {v}_{a 2} + {v}_{sp} - {v}_{a 2}^{″} - {v}_{sp}^{″} = {R}_{f} \cdot {i}_{f}\end{matrix} \qquad ( equation 5 )$$

where vₛₚ and vₛₚ″ are the winding star point voltages of the inner and outer conductors of the winding phases and i_{f} is the fault current between the inner conductor a and outer conductor a″.

Considering the expression for Lₐ₁, Lₐ₂, replacing equation 3 in equation 4 and rewriting the equations, the machine equations with coaxial cable insulation fault can be simplified as:

$$[ {V}_{sf} ] = [ {R}_{sf} ] \cdot [ {i}_{sf} ] + [ {L}_{sf} ] \cdot \frac{d}{d t} [ {i}_{sf} ] + [ {e}_{sf} ] \qquad ( equation 6 )$$

where [V_{sf}]=[[Vₛ], [v_{s″}]]^{t}, [i_{sf}]=[iₐ,i_{b},i_{c},i_{f}]^{t}, [e_{sf}]=[[eₛ],[eₛ″]]^{t}, and

$$[ {R}_{sf} ] = [ \begin{matrix}R & 0 & 0 & - μ R \\ 0 & R & 0 & 0 \\ 0 & 0 & R & 0 \\ 0 & 0 & 0 & μ {R}^{″} \\ 0 & 0 & 0 & 0 \\ 0 & 0 & 0 & 0\end{matrix} ] , [ {L}_{sf} ] = [ \begin{matrix}L & M & M & 0 \\ M & L & M & 0 \\ M & M & L & 0 \\ L & M & M & 0 \\ M & L & M & 0 \\ M & M & L & 0\end{matrix} ] .$$

Equation 6 shows the influence of i_{f} on the phase currents iₐ, i_{b}, i_{c}. As can be seen, due to the particular construction of the motor, in case of a fault in the insulation layer between the inner and outer conductor of the cable, the fault current does not influence the part of equation 6 that is due to magnetic flux linkage, but just the matrix of the resistances changes. This behaviour is different from that of a prior art PMSM, in which an inter-turn short circuit produces a change in the magnetic characteristic of the motor, that can be detected by analyzing the response of the motor to high frequency component superimposed with the supply voltages. Equation 6 indicates that this method may not be suitable for a motor according to an embodiment.

Moreover the third row of (5) leads to:

R_{f}i_{f}=μR(iₐ−i_{f})−μR″i_{f}+(vₛₚ−vₛₚ″) (equation 7)

The first term in equation 7 is mostly influenced by the supply current and, therefore, by the first harmonic of the supply frequency. The last term in equation 7 is significant, because of the induction effect from the rotor's permanent magnets. It difficult to produce an electric machine with sine-wave back electromotive force without the presence of electromotive force harmonics different from the fundamental. In presence of a third harmonic component in the back EMF, the center star voltage in a wye-connected stator oscillates at that frequency. The amplitude of the oscillation depends mainly on the particular geometry of the rotor magnets.

According to equation 7, if it is possible to pin the second end vₛₚ″ of the outer conductors a″, b″, c″ of each phase 210a, 210b, 210c to a fixed voltage value, (for example, the midpoint voltage of the DC power supply as shown in FIG. 3), the fault current will present a third harmonic component due to vₛₚ.

Moreover, according to equation 6, there is a relationship between i_{f} and the inner conductor currents iₐ, i_{b} and i_{c} of each stator phase winding. For this reason the spectrum of the stator currents of the inner conductors of the stator phase windings will present a third harmonic component originated by the short circuit R_{f} between the inner and the outer connector of the cable. Consequently, it is possible to detect faults in the insulation between the inner and outer conductor of the cable by analyzing the harmonic content of the current through the inner conductor.

It has been shown that in some embodiments, an incipient fault (i.e. a resistive short circuit) in the insulation layer between the inner and outer conductor of the cable results in a third harmonic component in the supply currents to the inner conductor. However. the amplitude of the resulting third harmonic tends to be much lower of that of the fundamental supply current. Furthermore, harmonics of supply current through the inner conductor are related to the load condition, the rotating speed, and to the severity and geometric position of the fault. For all these reasons monitoring the state of the machine by analysis of the harmonic content of the stator current through the inner conductor may be challenging under some circumstances. For instance, at low speed the accuracy with which the harmonics can be determined may be insufficient to detect the presence of a fault.

Although monitoring the harmonics of the supply current is one method for determining a fault in the stator that may be suitable under some circumstances (e.g. high speed operation), an alternative is to monitor the instantaneous active and reactive power absorption of the machine.

This technique, known as instantaneous p-q theory, has previously been employed in relation to power quality issues in power lines, but not to determine electrical faults in motors. This approach allows a time domain analysis of three-phase systems and has previously been applied to detect the harmonic content of the a power supply grid and to design and control active power filters.

A faulty motor can be considered a three-phase unbalanced system with harmonics, where currents and voltages are related according to equation 6. Therefore the acquired signals of currents and voltages can be utilized to compute the instantaneous power absorption of the motor and to perform a method for detecting an incipient fault occurrence. For this particular motor it most useful to employ the voltages [vₛ′] instead of the supply voltages [vₛ′] because the former are decoupled from the effects of the pulse width modulating converter.

An unbalanced three-phase system of voltages with harmonics can be generally written in the Clarke (or αβ0) reference frame:

$${v}_{α} = {\sum }_{n = 1}^{∞} \sqrt{3} {V}_{+ n} sin ( {ω}_{n} t + {φ}_{{V}_{+ n}} ) + {\sum }_{n = 1}^{∞} \sqrt{3} {V}_{- n} sin ( {ω}_{n} t + {φ}_{{V}_{- n}} ) \\ {v}_{β} = {\sum }_{n = 1}^{∞} \sqrt{3} {V}_{+ n} cos ( {ω}_{n} t + {φ}_{{V}_{+ n}} ) + {\sum }_{n = 1}^{∞} \sqrt{3} {V}_{- n} cos ( {ω}_{n} t + {φ}_{{V}_{- n}} ) \\ {v}_{0} = {\sum }_{n = 1}^{∞} \sqrt{6} {V}_{0 n} sin ( {ω}_{n} t + {φ}_{{V}_{0 n}} ) \qquad ( equation 8 )$$

In equation 8, V₊ₙ, V₋ₙ, V₀ₙ are the root mean square values of positive, negative and zero sequence voltage components for the n-th harmonic; ωₙ is the n-th harmonic angular frequency and the Φ_{V+n}, Φ_{V-n}, Φ_{V0n} are the phase angles of the n-th positive, negative and zero sequence voltage components. The same concept can be applied to the term of currents iₐ, i_{b}, i_{c}.

Expressing the real power p, imaginary power q, and zero sequence power p₀ in the Clarke reference frame:

p=v_{α}i_{α}+v_{β}i_{β}= p̅+\tilde{p}

q=v_{α}i_{β}−v_{β}i_{α}= q̅+\tilde{q}

p₀=v₀i₀= p̅₀+\tilde{p}₀ (equation 9)

Equation 8 describes the average ( p̅, q̅, p̅₀) and alternating parts (\tilde{p},\tilde{q},\tilde{p}₀) of the real, imaginary and zero sequence power.

By using equation 8 and the corresponding expressions for the currents in the Clarke reference frame, and considering only the fundamental and the third harmonic of current and voltage, it is possible to obtain the instantaneous real, imaginary and zero-sequence powers as:

$$p = \overline{p} + {\tilde{p}}_{2 ω} + {\tilde{p}}_{4 ω} + {\tilde{p}}_{6 ω} \\ q = \overline{q} + {\tilde{q}}_{2 ω} + {\tilde{q}}_{4 ω} + {\tilde{q}}_{6 ω} \\ {p}_{0} = {\overline{p}}_{0} + {\tilde{p}}_{0 \_ 2 ω} + {\tilde{p}}_{0 \_ 4 ω} + {\tilde{p}}_{0 \_ 6 ω} \\ {\tilde{p}}_{4 ω} = {\sum }_{m = 1 , 3} {\sum }_{{n = 1 , 3}_{n \neq m}} ( - 3 {V}_{+ m} {I}_{= n} cos ( ( {ω}_{m} + {ω}_{n} ) t + {φ}_{{V}_{+ m}} + {φ}_{{I}_{= n}} ) \\ - 3 {V}_{= m} {I}_{+ n} cos ( ( {ω}_{m} + {ω}_{n} ) t + {φ}_{{V}_{- m}} + {φ}_{{I}_{+ n}} ) ) \\ {\tilde{q}}_{4 ω} = {\sum }_{m = 1 , 3} {\sum }_{{n = 1 , 3}_{n \neq m}} ( 3 {V}_{+ m} {I}_{= n} sin ( ( {ω}_{m} + {ω}_{n} ) t + {φ}_{{V}_{+ m}} + {φ}_{{I}_{= n}} ) \\ - 3 {V}_{= m} {I}_{+ n} sin ( ( {ω}_{m} + {ω}_{n} ) t + {φ}_{{V}_{- m}} + {φ}_{{I}_{+ n}} ) ) \qquad ( equation 10 )$$

Equation 10 shows that there are second (2ω), fourth (4ω) and sixth (6ω) order harmonics for all real, imaginary and zero-sequence powers. In particular, the fourth order harmonics are given by the cross product of the fundamental of the voltages of the outer conductor with the third harmonic of the current of the inner conductor. This characteristic suggests that the fourth harmonic components will be present only in case of an incipient fault in the insulation layer between the inner and outer conductor of the cable of the stator phase winding.

Even if the amplitude of the third harmonic of the current is low, the fourth harmonic of the instantaneous powers should be significant because of the contribution of the fundamental of the supply voltage and may be straightforward to detect even where the speed is relatively low and the load relatively light. The most suitable fourth harmonic power is the real fourth harmonic power \tilde{p}_{4ω}.

As shown in equation 10, the 4^{th} order harmonic of the imaginary power \tilde{q}_{4ω} comprises components that differ in sign and the amplitude of \tilde{q}_{4ω} may therefore be lower than \tilde{p}_{4ω}. Moreover the amplitude of \tilde{p}₀_{_{—}}_{4ω} may be negligible because it is only due to the zero sequence components of current and voltage, that are low in case of incipient fault.

Although the fourth harmonic power (and specifically the real fourth harmonic power) may be a good candidate for determining faults, the use of other harmonic components may be used in some embodiments.

Referring to FIG. 4, a block diagram of a fault detection process 400 according to an embodiment of the invention is shown. The fault detection process comprises a first and second Clarke transformation block 401, 402; an instantaneous power block 403 and a harmonic estimation block 404.

The first Clarke transformation block 401 receives measured voltages vₐ″,v_{b}″,v_{c}″, measured at the first end of the outer conductors a″, b″, c″, and transforms these voltages into voltages v_{α}″,v_{β}″ in the αβ0 reference frame. The second Clarke transformation block 402 receives monitored currents iₐ, i_{b}, i_{c} and transforms these into currents i_{α}, i_{β} in the αβ0 reference frame.

The instantaneous power block 403 calculates the instantaneous real power p, from the currents and voltages in the Clarke reference frame. After computing the instantaneous real power, the fourth harmonic is detected by the harmonic estimation block 404. The harmonic estimation block 404 determines the average value of the instantaneous real power in a reference frame synchronous with the fourth harmonic of the electric angle. The Park transformation is used to convert from the stationary reference frame to the rotating dq0 frame. Since the rotating dq0 frame is synchronous with the fourth harmonic, the space-vector of \tilde{p}_{4ω} has constant components, whereas the space-vectors of all the other harmonics have pulsating components. An integral operator is used to integrate the value of the fourth harmonic of the instantaneous power in the dq0 reference frame, to provide an output pₙ_{₄}, from which the amplitude of the fourth harmonic, \tilde{p}_{4ω} may be determined.

FIG. 5 shows a model 500 for a PMSM having phase windings in accordance with an embodiment. This model was simulated using the PLECS toolbox in Simulink/Matlab® to investigate the effectiveness of fault detection.

The simulations were performed based on the electric parameters of reported in TABLE I, below.

TABLE 1
Electrical Parameters for the PM
Machine

| number of poles | 6 | |
|---|---|---|
| nominal speed | 3000 | rpm |
| nominal torque | 12.2 | Nm |
| nominal power | 3.82 | kW |
| Kt | 1.6 | Nm/A |
| Ke | 98 | Vrms/krpm |
| Inertia | 20.5 | kg/cm² |
| Phase resistance | 0.94 | Ω |
| Phase inductance | 8.3 | mH |

Each phase winding 210a, 210b, 210c in FIG. 5 is divided for simulation purposes into three identical sub-windings. The values adopted for the resistance R, R″ of the inner and outer conductors of each phase sub-winding in FIG. 5 were R=R″=0.94/3Ω. Values for self-inductance were L=L″=8.3/3 mH, and mutual inductances M=M″=−4.15/3 mH were adopted. Furthermore, the harmonic content of the back electromotive force e was included in the model, as having a value of third harmonic equal to one tenth of that of the fundamental. The square wave generators vₐ, v_{b}, v_{c} represent the output voltages of a pulse width modulated power converter employed to drive the motor. The resistor R_{f} was used to simulate damage in the insulator separating the inner and outer conductor of the cable of the first phase winding 210a.

In order to investigate the relatively challenging case of low speed and light load, simulations were performed using a mechanical speed range from 60 to 120 rpm, a rated torque of 1 Nm, and a rated current of 1 A. These values are considerably lower than the rated nominal values reported in Table 1.

FIG. 6 shows the relationship between the amplitude of the fourth harmonic of the real power \tilde{p}_{4ω} with the value of the fault resistance R_{f}, at a motor speed w_{mecc}=60 rpm and motor torque Tᵣ=1 Nm. The curve in FIG. 6 is for a fault resistor connected between 3 and 3″.

It is possible to identify two regions of operation. In the first region 601, when the value of fault resistance R_{f} is high, the amplitude of the fourth order harmonic of the real power \tilde{p}_{4ω} is nearly constant and is relatively low. In the second region 602, once the value of R_{f} has sufficiently decreased (i.e. when the fault is sufficiently severe), the amplitude of \tilde{p}_{4ω} starts to rise substantially linearly with decreasing R_{f}. The value of R_{f} at which the transition between the two regions 601, 602 takes place is approximately 10Ω. This indicates that methods according to an embodiment are able to detect incipient faults at an early stage when the insulating layer is starting to degrade, but before a potentially dangerous full short circuit has occurred.

FIG. 7 shows the relationship between the amplitude of the fourth harmonic of the real power \tilde{p}_{4ω} with the speed of the motor (from 30 to 120 rpm), for a value of the fault resistance R_{f}=10Ω and motor torque Tᵣ=1 Nm. As expected \tilde{p}_{4ω} varies in a linear relationship with the speed of the motor.

Simulations also show that \tilde{p}_{4ω} is dependent on the geometric position of the fault, which may be used to determine a location of the fault.

FIG. 8 shows the relationship between the amplitude of the fourth harmonic of the real power \tilde{p}_{4ω} and the fault resistance for three different locations of the fault resistor. The conditions are otherwise the same as those in FIG. 6. Curves 801, 802, 803 are respectively shown for the fault resistor R_{f} connected between 1 and 1″, 2 and 2″ and 3 and 3″.

In can be seen the value of \tilde{p}_{4ω} increases as the fault is nearer to the first end 201 of the phase. This is because, for a fault near to the first end 201 the fault current is multiplied by a higher value of mutual inductance, which means that a given value of R_{f}, has greater effect on the system when the fault is closer to the first end 201.

The arrangement of FIG. 2, in which the second end 202 of the outer conductors are connected together in a wye configuration to the middle point of the DC link (V_{DC}/2) allows detection of incipient faults but has a strong dependence on the load conditions, the rotating speed of the machine and the position of the fault. If the fault occurs near the first end 201 of the windings 210a, 210b, 210c, the fault current amplitude will be greater that would be the case if a fault occurred near the second end 202 of the windings. In particular, if the degradation of the insulation layer occurs at the star point, the presence of the fault may not be detected at all. This drawback is partially mitigated by the fact that degradation of the insulation layer is more likely near the terminals of the windings. This is because, the electrical stress on the insulation layer, due to the PWM approach, is not uniformly distributed along the windings, but it is more prominent in the first turns of the windings.

Moreover, detecting a fault using the arrangement of FIG. 2 may require three current sensors and three voltage sensors. Although two current sensors may be sufficient for driving a motor, in reliable applications three current sensors are usually often embedded in the VSC, for example to enable alternative control strategies in case of breakdown of one phase of the drive. Therefore, no additional current sensors are typically required for monitoring incipient faults.

However, voltage sensors for monitoring the voltage of the outer conductors are not part of a conventional VSC. In fact, even if information about the supply voltages of the motor is required for realizing sensorless controls, the information is typically obtained from the digital variables of the controller, which do not suffer of PWM effects, and therefore no voltage sensors are typically provided.

An alternative to the approach described above in connection with the arrangement of FIG. 2 is to add a current sensor in a path that connects a center star 250, of the outer conductors of the windings to the mid-point of the DC source. This approach is illustrated in FIG. 9.

The current that flows in the fault resistance is the same that circulates in the connection between the neutral point of the search winding and the mid-point of the DC-link. This approach allows the detection of a fault current i_{f}, even if the fault is at the center star point 250, of the windings 210a, 210b, 210c. Due to the low amplitude of the fault current i_{f} with respect to the supply currents to the inner conductors of the motor windings, the current sensor employed for sensing such a fault current i_{f} may be separate from those used for the main windings Ideally it should be more sensitive. Commercially available current sensors that can detect a current with amplitude of few mA do not typically have a high maximum current rating, and damage of the sensor may arise in the case of an incipient fault comprising a severe short-circuit.

An alternative arrangement that may reduce this problem is to rearrange the phase connections in order to change the position of the terminals of the search windings as shown in FIGS. 10 and 11. In this arrangement, the terminals of the outer conductors are at the second end 202 of the windings, and at the first end 201 the outer conductors are connected together in to the mid point of the DC link.

In this way the positions of the terminals of the inner conductors and the outer conductors are inverted and the differential voltage between them is higher than in the previous case. Consequently, for a given value of fault resistance R_{f}, the fault current i_{f}, is greater. A less sensitive current sensor with higher maximum current rating can be subsequently used to detect the presence of a fault. However, with this approach the electrical stress on the insulation layer of the coaxial cable is greater, which may reduce the motor lifetime.

In other arrangements, the star connection 250 of the outer conductors of the windings may be between the first end 201 and the second end 202. For instance, each phase winding may comprise a series of sub-windings, between which connections may conveniently be made to the outer conductor. The star point 250 may again be connected to the mid point of the DC link. Providing a star point connection 250 between the first end 201 and the second end 202 of the phase windings results in a voltage that is reduced in proportion to the proximity of the star point 250 to the first end 201 of the windings 210a, 210b, 210c. For instance, a voltage difference between the inner and outer conductor limited to half that of the DC link can be provided by connecting the middle point of the outer conductor of the windings to the midpoint of the DC link, as shown in FIG. 12.

As shown in both FIGS. 11 and 12, the voltage V dropped over a current monitoring resistor R_{cm}, can be used to infer the fault current i_{f}.

The method proposed with reference to FIGS. 9 to 12 adopts only one additional current sensor compared to a conventional VSC, and no additional voltage sensors. Therefore it presents a lower impact in term of costs respect to a solution in which the terminals of the outer conductor are at the same end of the winding as the terminals for the inner conductor. Moreover, the complexity of the calculation for determining a fault is reduced. No complex calculation is needed, and a comparator is sufficient to easily detect the presence of an incipient fault.

Experimental tests were performed with a prototype motor whose electric parameters are shown in Table 2.

TABLE 2
Electrical Parameters for the PM
Machine

| number of poles | 28 | |
|---|---|---|
| nominal speed | 5000 | rpm |
| nominal torque | 15 | Nm |
| nominal power | 7.85 | kW |
| Kt | 1.6 | Nm/A |
| Ke | 1.3 | Vrms/krpm |
| Phase resistance | 0.94 | Ω |
| Phase inductance | 2.42 | mH |

In order to simulate a PMSM with coaxially insulated windings, an additional wire was added in each phase in order to simulate the presence of the outer conductor of the cable.

Several points of access to the windings were provided to reproduce different fault positions. The fault resistance R_{f} was simulated with a variable resistor connected between the main conductor (representing the inner conductor) of each winding and the additional wire (representing the outer conductor), as shown in FIG. 11.

Values of 100, 10, 1, 0.2Ω for the fault resistance R_{f} were used to simulate different severity levels of the incipient fault. The variable resistor was disconnected when the behavior of the healthy motor was reproduced.

In order to prove the feasibility of the proposed diagnostic method in the case of low speed and light load, experimental testing was performed using a mechanical speed range from 180 to 780 rpm, and a rated torque of 1 Nm. These values are considerably lower than the nominal ones reported in Table 2.

A number of theoretical and experimental results are shown in FIGS. 14a to 14f. In these drawings curves relating to rotational speeds of ωᵣ=188, 386 and 574 rpm are respectively indicated by 1401, 1402 and 1403. Curves relating to fault positions 1-1″, 2-2″ and 3-3″ are respectively denoted by 1404, 1405, 1406.

In FIGS. 14a and 14b the calculated amplitude of the fourth harmonic of the instantaneous active power in the αβ0 reference frame is reported for different values of fault resistance R_{f} and mechanical speed ωᵣ (FIG. 14a). FIG. 14b shows the same power as a function of ωᵣ when the fault resistance Rf=10Ω and different positions for the incipient fault are considered (1-1′, 2-2′ and 3-3′ in FIG. 5). The fourth harmonic of the instantaneous active power in the αβ0 reference frame shows a linear dependence with the motor speed, the severity of the fault and the position of the fault. Furthermore, two regions of operation can be identified. When the value of the fault resistance R_{f} is high, the amplitude of forth harmonic is nearly constant. When the severity of the fault increases (i.e R_{f} decreases), the amplitude starts to rise linearly. The value of R_{f} between the two states of behavior is near 10Ω. FIGS. 14c and 14d show the amplitude of the third harmonic of the fault current, detected with the previously discussed method, in the same test conditions as FIGS. 14a and 14b respectively. As expected, the fault can be detected even when it occurs at the star center 250 of the windings.

FIGS. 14e and 14f show the amplitude of the third harmonic of the fault current i_{f} under the same test conditions, but when the windings are connected as in FIG. 10. The current amplitude is greater than those shown in FIGS. 14c and 14d, as expected. Although an additional current sensor is required, arranging the outer conductor to be at a different voltage to the inner conductor enables a simpler detection method for incipient faults. Moreover this method is still able to detect relatively high value of fault resistance R_{f}, so is suitable for detecting incipient faults even in their early stage.

In some embodiments, the outer conductor may be biased by an external voltage or current source, to provide further control over the voltage difference and/or fault current between the inner and outer conductors. This approach can be applied regardless of the configuration and connections of the outer conductor, and is applicable to all embodiments.

In an alternative arrangement, there may be no insulating layer over the outer conductor, so that the outer conductors of each turn of each winding (and/or each winding) are electrically connected together. This outer conducting layer may be arranged to be at a different voltage to the inner conductor, so that a fault current arises when an electrical connection is made between the inner and outer conductors. The outer conducting layer may have a relatively high resistivity for this approach, and/or may comprise a thin conducting layer. The conducting layer may be less than: 10 μm, 1 μm, 500 nm, 200 nm or 100 nm thick. The sheet resistance of the conducting layer may be less than 10 ohm/sq, 5 ohm/sq, 1 ohm/sq, or 0.1 ohm/sq.

The inner conductor and outer conductor may comprise any suitable material, for example a metal such as copper or aluminium. In some arrangements, the outer conductor may have a relatively high resistivity, and may comprise a semiconductor material. Since the outer conductor does not normally carry current (except in the case of a fault condition) it may be very thin, for example having a cross sectional area of less than 1 mm, 0.5 mm², 0.25 mm², 0.1 mm² or 0.05 mm². The insulator between the inner and outer conductors and the insulator around the outer conductor may each comprise any suitable material, for example a varnish or polyimide material (e.g. Kapton®). Each of the insulators may be spray coated, or deposited or coated in some other way. The insulator between the inner conductor and the outer conductor may comprise a metallised polyimide film, or a polyimide film coated with a conducting resin, polymer or varnish.

FIG. 15 shows a flow diagram of a method of monitoring a motor for a fault condition, comprising a number of steps 901-904. The first step 901 comprises providing a motor with one or more windings having inner and outer conductors separated by an insulator, in accordance with an embodiment of the invention. The second step 902 comprises operating the motor by driving current through the inner conductors of the one or more windings. The third step 903 comprises monitoring an electrical property of the inner and/or outer conductor as the motor is operated. The fourth step 904 comprises determining whether there is a fault condition based on the monitoring.

The skilled person will appreciate that a number of modifications can be made to the example embodiments, within the scope of the invention, as defined by the appended claims. For example, the electric machine could be a generator, so that the currents flowing in the stator are induced by mechanical power applied to the rotor, rather than applied by a motor drive. In another arrangement, the rotor could be wound and the stator could comprise a permanent magnet (e.g. the electric machine could be a brushed DC motor).

1. An electric machine comprising a rotor or stator winding, wherein the winding comprises a cable that includes an inner conductor and an outer conductor, and an insulator separating the inner conductor from the outer conductor.

2. The electric machine of claim 1, wherein the cable is a coaxial cable.

3. The electric machine of claim 1, wherein the inner conductor comprises a plurality of insulated wires, and the outer conductor comprises a conducting sleeve around the inner conductor.

4. The electric machine of claim 1, wherein the electric machine is a permanent magnet synchronous machine, and the winding comprises a plurality of stator phase windings.

5. The electric machine of claim 4, wherein there are three phase windings, each phase winding comprising a cable with an inner conductor and an outer conductor, and an insulator separating the inner conductor from the outer conductor.

6. The electric machine of claim 5, wherein each winding comprises a first end and a second end, and the inner conductors of each winding are connected together at the second end of each winding in a wye configuration.

7. The electric machine of claim 6, wherein the outer conductors of each winding are connected together in a wye configuration at the second end of the winding.

8. The electric machine of claim 6, wherein the outer conductors of each winding are connected together in a wye configuration at the first end of the winding or at a point between the first and second end of the winding.

9. The electric machine of claim 1, further comprising a fault detection circuit connected to the outer conductor, the fault detection circuit being configured to monitor an electrical property of the outer conductor to determine a fault condition.

10. The electric machine of claim 9, wherein the electrical property of the outer conductor comprises a current or a voltage.

11. The electric machine of claim 10, wherein the outer conductors of each winding are connected together in a wye configuration at the first end of the winding or at a point between the first and second end of the winding and wherein the fault detection circuit is arranged to monitor a current in the outer conductor through a star point of the wye configuration.

12. The electric machine of claim 8, wherein the fault detection circuit is arranged to monitor the current provided to the inner conductor of each winding.

13. The electric machine of claim 9 wherein the fault detection circuit is configured to determine a fault condition based, at least in part, on at least one of:
a harmonic content of the monitored current in the inner or outer conductor; and
an amplitude of the third order harmonic content of the monitored currents in the inner or outer conductor.

14. The electric machine of claim 13, wherein the fault detection circuit is configured to perform a Clarke transformation on monitored voltages of the outer conductor and monitored currents of the inner conductor, and to determine a power in the Clarke reference frame therefrom.

15. The electric machine of claim 14, wherein the power comprises a real power, and the fault detection circuit is configured to perform a harmonic analysis on the real power, and to determine a fault condition based, at least in part, on the results of the harmonic analysis.

16. The electric machine of claim 15, wherein the fault detection circuit is configured to perform a Park transform on the instantaneous real power prior to performing the harmonic analysis.

17. The electric machine of claim 15 wherein the results of the harmonic analysis comprise an amplitude of a fourth order harmonic, and the fault condition is determined based, at least in part, on the amplitude of the fourth order harmonic.

18. The electric machine of claim 1, wherein the insulator comprises polyimide, the outer conductor comprises aluminium, and the cable comprises a further insulating layer of polyimide surrounding the outer conductor.

19. The electric machine of claim 1, wherein the insulator comprises polyimide and the outer conductor comprises one of metallised polyimide and a conductive varnish layer.

20. (canceled)

21. The electric machine of claim 1, wherein there is not an insulator layer surrounding the outer conductor.

22. An aircraft comprising an electric machine the electric machine comprising a rotor or stator winding, wherein the winding comprises a cable that includes an inner conductor and an outer conductor, and an insulator separating the inner conductor from the outer conductor.

23. A method of monitoring for faults in an electric machine the electric machine comprising a rotor or stator winding, wherein the winding comprises a cable that includes an inner conductor and an outer conductor, and an insulator separating the inner conductor from the outer conductor, the method comprising:
operating the electric machine by rotating a rotor of the machine, and
monitoring at least one electrical property of the inner conductor and/or the outer conductor as the electric machine is operated to determine whether a fault condition exists.

24. The method of claim 23, wherein the at least one electrical property comprises at least one of:
a current flowing through the inner conductor;
a harmonic content of the current flowing through the inner conductor
a third harmonic content of the current provided to the inner conductor; and
a voltage or current of the outer conductor.

25. The method of claim 24, wherein the at least one electrical property comprises the current flowing in the inner conductor of each winding and a voltage of the outer conductor of each phase winding, the method comprising performing a Clarke transformation on the current flowing in the inner conductor and on the voltages of the outer conductor, and determining a power in the Clarke reference frame based on the voltages and currents.

26. The method of claim 25, wherein the power comprises a real power, and the method comprises performing a harmonic analysis on the real power.

27. The method of claim 26, comprising performing a Park transform on the real power prior to performing the harmonic analysis.

28. The method of claim 27, wherein performing the harmonic analysis comprises determining an amplitude of a fourth order harmonic of the real power in the dq0 reference frame.

29. A rotor or stator for an electric machine, comprising a winding, the winding comprising a cable that includes an inner conductor and an outer conductor, and an insulator separating the inner conductor from the outer conductor.

30.-31. (canceled)
